(19) United States
(12) Patent Application Publication
(10) Pub. No.: US 2025/0203899 A1
(43) Pub. Date: Jun. 19, 2025

(54) METHOD FOR MANUFACTURING GROUP 3 NITRIDE SEMICONDUCTOR TEMPLATE USING DOUBLE SEED LAYER

(71) Applicant: WAVELORD CO., LTD, Hwaseong-si (KR)

(72) Inventors: Juneo SONG, Suwon-si (KR); Hyeong Seon YUN, Paju-si (KR); Young Hun HAN, Osan-si (KR); Ji Hyung MOON, Gunpo-si (KR); WY IL YUN, Hwaseong-si (KR); Jin Hyoung CHO, Seongnam-si (KR)

(73) Assignee: WAVELORD CO., LTD, Hwaseong-si (KR)

(21) Appl. No.: 18/860,676

(22) PCT Filed: Feb. 8, 2024
(86) PCT No.: PCT/KR2024/001893

§ 371 Date: Oct. 27, 2024

(30) Foreign Application Priority Data
Feb. 15, 2023 (KR) 10-2023-0020052

(51) Int. Cl. H10D 30/01; H01L 21/02; H01L 21/304; H10D 62/85

(52) U.S. Cl. CPC H10D 30/015; H01L 21/02458; H01L 21/02505; H01L 21/304; H10D 62/8503

(57) ABSTRACT

The present invention relates to a method for manufacturing a Group 3 nitride semiconductor template using a double seed layer, in which a high-quality Group 3 nitride power semiconductor device layer is grown through a double seed layer comprising a first seed layer formed ex-situ at a low temperature and a second seed layer formed in-situ at a high temperature, so that a vertical leakage current can be minimized.

### TECHNICAL FIELD

The present invention relates to a method of manufacturing a group 3 nitride semiconductor template using a double seed layer, and more specifically, to a method of manufacturing a group 3 nitride semiconductor template using a double seed layer in which a high-quality group 3 nitride power semiconductor device layer may be grown through a double seed layer including a first seed layer formed ex-situ at a low temperature and a second seed layer formed in-situ at a high temperature.

### BACKGROUND ART

FIG. 1 shows a power semiconductor device grown on the conventional Si or SiC growth substrate.

As shown in FIG. 1, a conventional power semiconductor device 10 has a structure in which an AlN seed layer 12 and a stress relief layer 13, which function as a re-melting prevention layer, are sequentially stacked on an Si (or SiC) single crystalline growth substrate 11, and then a power semiconductor device (a high resistance layer 14, a channel layer 15, a barrier layer 16) such as a high energy mobility transistor (HEMT) is formed on the stress relief layer 13, and here, as a crystal face of the Si single crystalline growth substrate 11, a (111) face in which Si atomic bonds are most dense is preferentially used, but it is known that a (110) or (100) face is also used depending on the product application.

In addition, a metal organic chemical vapor deposition (MOCVD) device is usually used for growing a GaN material-based single crystalline thin film, and during the growth (deposition) process at a high temperature of about 1000° C. and in a reducing atmosphere (H2, H+, NH3, or radical ions), the AlN seed layer 12 made of an AlN material is formed before the stress relief layer 13 is formed to block the occurrence of a metallic eutectic reaction between a surface of the Si single crystalline growth substrate 11 and Ga atoms. The AlN seed layer 12 may be grown in-situ in an MOCVD chamber and formed ex-situ before loading into the MOCVD chamber using another external deposition (growth) process device.

In particular, studies recently have reported that when an ex-situ AlN seed layer 12 formed using a physical vapor deposition (PVD) (sputtering, pulse laser deposition (PLD), or an E-beam evaporator) or atomic layer deposition (ALD) process at a low temperature of 700° C. or lower is used, the nuclei density of a GaN material is about 3 times lower than that of an in-situ AlN seed layer 12 grown at a high temperature using a MOCVD process, thereby reducing crystal defects.

However, when using the ex-situ AlN seed layer 12 using the PVD or ALD process, the surface roughness and crystal quality (axis orientation and in-plane ordering) of the ex-situ AlN seed layer 12 greatly affects the quality of the continuously grown group 3 nitride (AlGaN or GaN) epitaxy, and due to the characteristics of the ex-situ AlN seed layer 12 formed at a low temperature, there are problems that it is difficult for the axis orientation of the crystal quality to be 100% identical to a growth axis (c-axis), and at the same time, the in-plane ordering within the crystal growth face is not in a perfect state.

In addition, when the ex-situ AlN seed layer 12 is loaded into the MOCVD chamber to grow a group 3 nitride semiconductor layer on the ex-situ AlN seed layer 12, surface roughness becomes severe due to the recrystallization and decomposition of the ex-situ AlN seed layer 12 that occur as the temperature rises to a high temperature of 900° C. or higher, and thus there is still a limit to reducing crystal defects.

Furthermore, in power semiconductor devices, a major issue is to minimize a lateral leakage current in a lateral direction proportional to a distance between a gate and a drain and a vertical leakage current in a vertical direction that occurs depending on the quality of an epitaxial layer when operating in an off state, and since products currently on the market may not minimize the vertical leakage current, their quality is low in terms of reliability and there is a limitation that the products may only be applied as low-power (lower than 650 V) devices.

That is, in order for the products to be applied as high-power devices, it is most important to first improve the crystal quality of each layer constituting a group 3 nitride semiconductor grown on an Si (silicon) or SiC (silicon carbide) single crystalline growth substrate to minimize the vertical leakage current.

### DISCLOSURE

### Technical Problem

The present invention is intended to solve the above-described conventional problems and is directed to providing a method of manufacturing a group 3 nitride semiconductor template using a double seed layer in which a high-quality group 3 nitride power semiconductor device layer may be grown through a double seed layer including a first seed layer formed ex-situ at a low temperature and a second seed layer formed in-situ at a high temperature.

### Technical Solution

The above object is achieved by a method of manufacturing a group 3 nitride semiconductor template using a double seed layer, which includes forming a first seed layer on a growth substrate, heat-treating the first seed layer, planarizing a surface of the heat-treated first seed layer, growing a second seed layer on the planarized first seed layer, and growing a stress relief layer on the second seed layer.

In addition, the method according to the present invention may further include growing a power semiconductor device layer on the stress relief layer.

In addition, the first seed layer may be formed ex-situ at a low temperature of 700° C. or lower, and the second seed layer may be formed in-situ at a high temperature of 900° C. or higher.

In addition, the planarizing of the surface of the heat-treated first seed layer may include planarizing the surface of the first seed layer through chemical-mechanical polishing (CMP).

In addition, the growing of the second seed layer may include growing the second seed layer on the first seed layer on which a masking layer is formed after forming the masking layer on a part in which grain boundaries or defects are present in the surface of the first seed layer.

In addition, air voids may be formed inside the second seed layer.

The above object is achieved by a method of manufacturing a group 3 nitride semiconductor template using a double seed layer, which includes growing a second seed layer on a growth substrate, forming a first seed layer on the second seed layer, heat-treating the first seed layer, planarizing a surface of the heat-treated first seed layer, and growing a stress relief layer on the planarized first seed layer.

In addition, the method according to the present invention may further include growing a power semiconductor device layer on the stress relief layer.

In addition, the first seed layer may be formed ex-situ at a low temperature of 700° C. or lower, and the second seed layer may be formed in-situ at a high temperature of 900° C. or higher.

In addition, the planarizing of the surface of the heat-treated first seed layer may include planarizing the surface of the first seed layer through CMP.

In addition, the growing of the stress relief layer may include growing the stress relief layer on the first seed layer on which a masking layer is formed after forming the masking layer on a part in which grain boundaries or defects are present in the surface of the first seed layer.

In addition, air voids may be formed inside the stress relief layer.

### Advantageous Effects

According to the present invention, it is possible to minimize a vertical leakage current by growing a high-quality group 3 nitride power semiconductor device layer through a double seed layer, thereby significantly improving the reliability of a power semiconductor device.

Meanwhile, the effects of the present invention are not limited to the above-described effects, and may include various effects within a range that is apparent to those skilled in the art from the following descriptions.

### DESCRIPTION OF DRAWINGS

FIG. 1 shows a power semiconductor device grown on the conventional Si or SiC growth substrate.

FIG. 2 is a flowchart of a method of manufacturing a group 3 nitride semiconductor template using a double seed layer according to a first embodiment of the present invention.

FIG. 3 shows a process of manufacturing a group 3 nitride semiconductor template according to the method of manufacturing a group 3 nitride semiconductor template using a double seed layer according to the first embodiment of the present invention.

FIG. 4 shows group 3 nitride semiconductor templates manufactured on different growth substrates in the method of manufacturing a group 3 nitride semiconductor template using a double seed layer according to the first embodiment of the present invention.

FIG. 5 is a flowchart of a method of manufacturing a group 3 nitride semiconductor template using a double seed layer according to a second embodiment of the present invention.

FIG. 6 shows a process of manufacturing a group 3 nitride semiconductor template according to the method of manufacturing a group 3 nitride semiconductor template using a double seed layer according to the second embodiment of the present invention.

FIG. 7 shows group 3 nitride semiconductor templates manufactured on different growth substrates in the method of manufacturing a group 3 nitride semiconductor template using a double seed layer according to the second embodiment of the present invention.

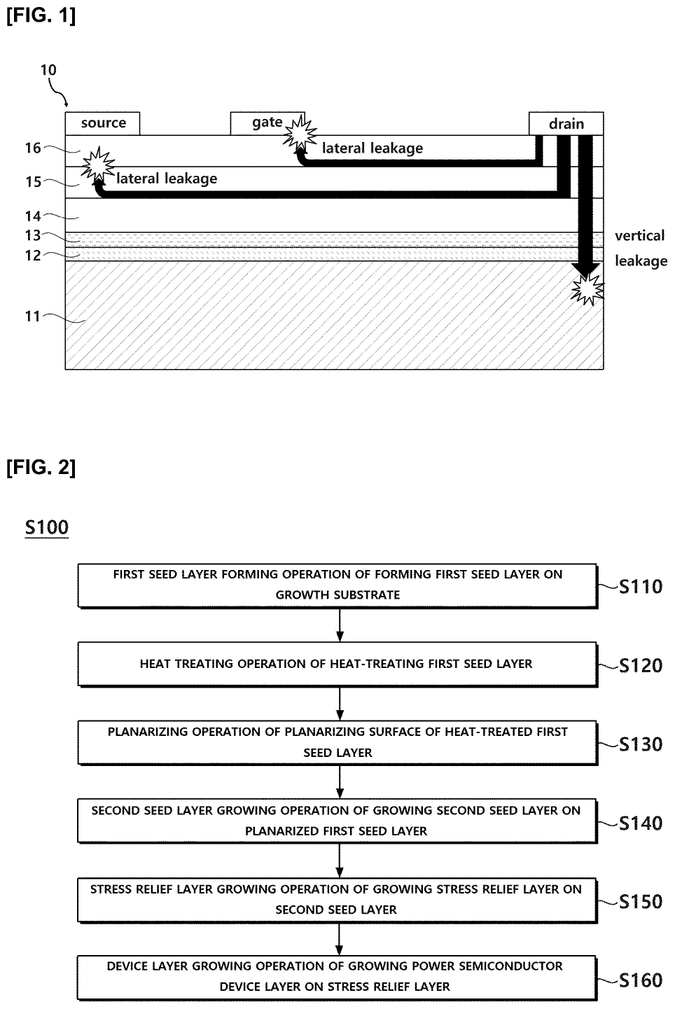

### MODES OF THE INVENTION

Hereinafter, some embodiments of the present invention will be described in detail with reference to exemplary drawings. In adding reference numerals to components in each drawing, it should be noted that the same components have the same reference numerals as much as possible even when they are illustrated in different drawings.

In addition, in describing embodiments of the present invention, detailed descriptions of related known configurations or functions will be omitted when it is determined that the detailed descriptions obscure the understanding of the embodiments of the present invention.

In addition, terms such as first, second, A, B, (a), and (b) may be used to describe components of the embodiments of the present invention. These terms are only for the purpose of distinguishing one component from another component, and the nature, sequence, order, or the like of the corresponding component is not limited by the terms.

Hereinafter, a method S100 of manufacturing a group 3 nitride semiconductor template using a double seed layer according to the first embodiment of the present invention will be described in detail with reference to the accompanying drawings.

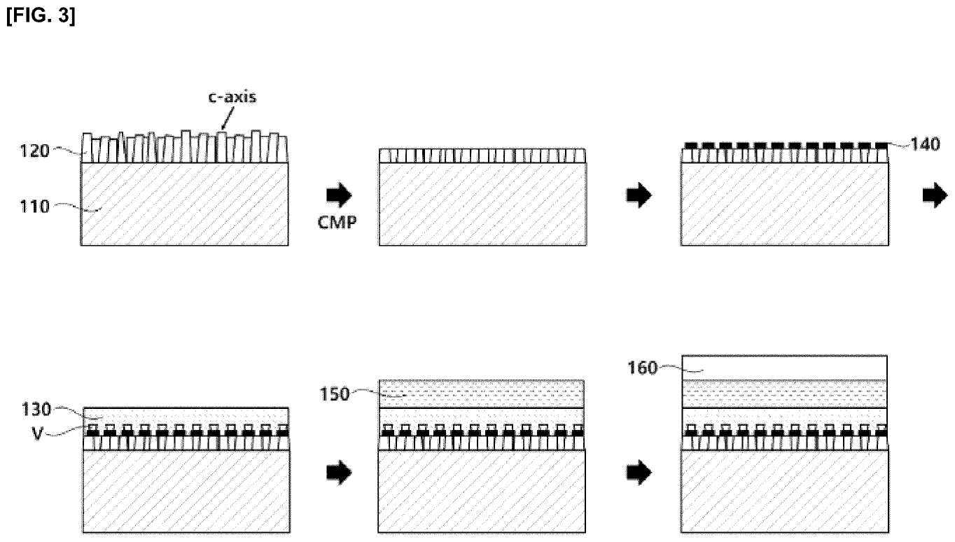

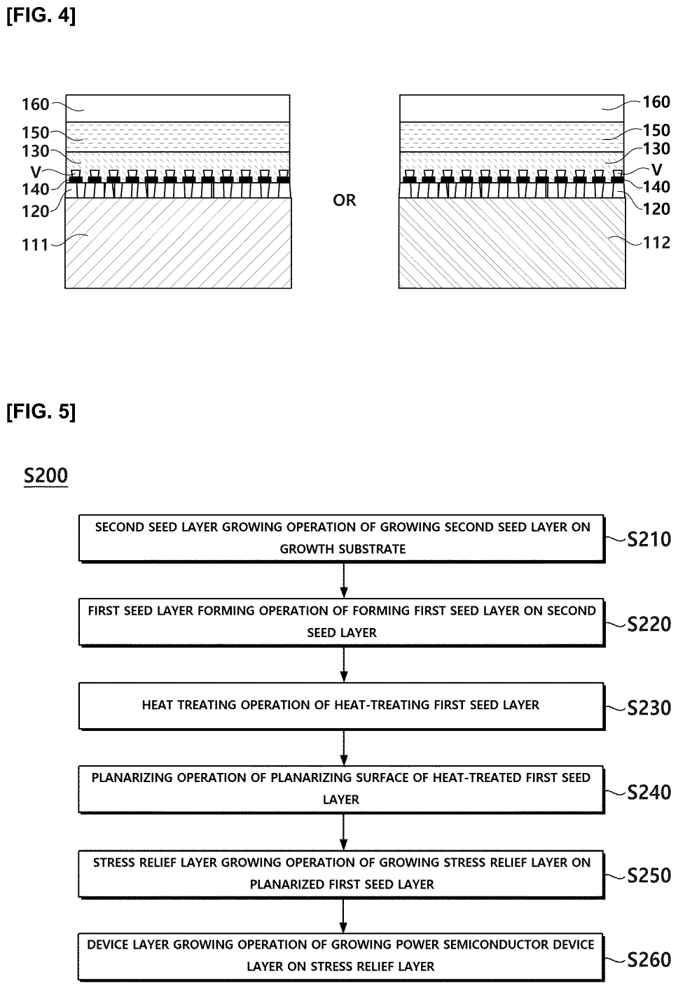

FIG. 2 is a flowchart of a method of manufacturing a group 3 nitride semiconductor template using a double seed layer according to a first embodiment of the present invention, FIG. 3 shows a process of manufacturing a group 3 nitride semiconductor template according to the method of manufacturing a group 3 nitride semiconductor template using a double seed layer according to the first embodiment of the present invention, and FIG. 4 shows group 3 nitride semiconductor templates manufactured on different growth substrates in the method of manufacturing a group 3 nitride semiconductor template using a double seed layer according to the first embodiment of the present invention.

As shown in FIGS. 2 to 4, the method S100 of manufacturing a group 3 nitride semiconductor template using a double seed layer according to the first embodiment of the present invention includes a first seed layer forming operation S110, a heat treating operation S120, a planarizing operation S130, a second seed layer growing operation S140, a stress relief layer growing operation S150, and a device layer growing operation S160.

The first seed layer forming operation S110 is an operation of forming a first seed layer 120 on a growth substrate 110.

The first seed layer 120, a second seed layer 130, a masking layer 140, a stress relief layer 150, and a power semiconductor device layer 160 are formed and stacked on the growth substrate 110, and the growth substrate 110 may be provided as an Si single crystalline growth substrate 111 and as a crystal face, a (111) face in which Si atomic bonds are most dense may be preferentially used, but a (110) or (100) face may also be used depending on the product application. Furthermore, in the case of devices requiring high heat dissipation specifications, the growth substrate 110 may be changed to an SiC growth substrate 112. That is, in the present invention, the growth substrate 110 including Si may be used as the growth substrate 110, and for convenience of description, the following description will be made based on the Si growth substrate 111.

The first seed layer 120 is formed ex-situ on the growth substrate 110 at a low temperature of 700° C. or lower through a physical vapor deposition (PVD) (sputtering, pulse laser deposition (PLD), and/or an E-beam evaporator) or atomic layer deposition (ALD) process, and the first seed layer 120 may be formed of AlN or AlNO (within 10 atomic percent (at %) during the layer forming process).

Specifically, in the first seed layer forming operation S110, the first seed layer 120 is formed by cleaning the growth substrate 110 to remove native oxide (SiO2) and then forming an AlN or AlNO layer (within 10 atomic percent (at %) during the layer forming process) to a thickness of 200 nm or less using a PVD or ALD process.

In this case, a surface polarity of the first seed layer 120 has a mixed polarity surface in which Al-polarity and N-polarity are mixed and has a surface state in which a c-axis is hardly exposed.

The heat treating operation S120 is an operation of heat-treating the formed first seed layer 120 at a high temperature of 1000° C. or higher. That is, through the pre-heat-treated first seed layer 120, in the second seed layer growing operation S140 to be described below, the second seed layer 130 may be grown with high quality on the first seed layer 120 even at a high temperature of 900° C. or higher inside a metal organic chemical vapor deposition (MOCVD) chamber.

The planarizing operation S130 of the present invention is an operation of planarizing the surface of the heat-treated first seed layer 120.

The ex-situ AlN or AlNO seed layer formed using the PVD (sputtering, PLD, or an E-beam evaporator) or ALD process at a low temperature of 700° C. or lower has the nuclei density of a GaN material that is about 3 times lower than that of the in-situ AlN seed layer, thereby reducing crystal defects, but there are problems that a surface roughness value is basically large, it is difficult for the axis orientation of the crystal quality to be 100% identical to a growth axis (c-axis), and at the same time, the in-plane ordering within the crystal growth face is not in a perfect state.

Therefore, the planarizing operation S130 of the present invention is an operation of improving surface roughness by planarizing the surface of the heat-treated first seed layer 120 through chemical-mechanical polishing (CMP) and at the same time, increasing an exposed area of the c-axis.

In this case, the thickness of the first seed layer 120 remaining after CMP is preferably 100 nm or less, and the surface roughness value of the first seed layer 120 after CMP is preferably 0.5 nm or less.

The second seed layer growing operation S140 is an operation of growing the second seed layer 130 on the planarized first seed layer 120.

More specifically, the second seed layer 130 may be grown in-situ on the first seed layer 120 at a high temperature of 900° C. or higher through MOCVD, the second seed layer 130 may be made of AlN, similar to the first seed layer 120, and the thickness of the second seed layer 130 is not limited.

In this case, in the second seed layer growing operation S140, before growing the second seed layer 130 on the first seed layer 120, the masking layer 140 made of SiNx may be formed. That is, in the second seed layer growing operation S140, the masking layer 140 may be formed so that SiNx crystal particles are preferentially located in a part in which grain boundaries or defects are present on the surface of the first seed layer 120, and then the second seed layer 130 may be grown on the first seed layer 120 on which the masking layer 140 is formed, thereby significantly improving the crystal quality of the second seed layer 130.

Furthermore, in the second seed layer growing operation S140, a growth mode may be controlled to form an air void V inside the second seed layer 130.

More specifically, since the masking layer 140 is formed only in the part in which grain boundaries or defects are present on the surface of the first seed layer 120, the masking layer 140 has unevenness, and in the second seed layer growing operation S140, the second seed layer 130 may be grown through primary AlN growth reinforced vertically and secondary AlN growth reinforced laterally by the masking layer 140 having such unevenness. According to the growth method, since a number of air voids V may be formed inside the second seed layer 130, tensile stress may be relieved to effectively suppress the occurrence of cracks in the template and grow the thick second seed layer 130.

The stress relief layer growing operation S150 is an operation of growing the stress relief layer 150 on the second seed layer 130.

More specifically, the stress relief layer growing operation S150 is an operation of growing an AlxGal-xN layer, which is a ternary material in which an Al composition decreases in a gradual or stepwise manner and a Ga composition increases in a gradual or stepwise manner, on the second seed layer 130. In this case, the thickness of the stress relief layer 150 being grown may be preferably 5 μm or less and may have superlattices (SLs) made of AlN/GaN, AlN/AlGaN, AlGaN/GaN, or AlxGal-xN/AlyGal-yN.

The device layer growing operation S160 is an operation of growing the power semiconductor device layer 160, such as a high energy mobility transistor (HEMT), on the stress relief layer 150.

More specifically, the device layer growing operation S160 may sequentially grow a high-resistance layer, a channel layer, and a barrier layer on the stress relief layer 150, in which the high-resistance layer may be made of GaN doped with carbon (C) or iron (Fe), the channel layer may be made of undoped GaN, and the barrier layer may be made of AlGaN, InGaN, AlScN, etc. In addition, a passivation layer such as SiNx, AlN, or GaN may be formed on the barrier layer by an MOCVD in-situ process, and in some cases, a p-type semiconductor layer such as pGaN or pAlGaN may be grown before the passivation layer is formed.

Hereinafter, a method S200 of manufacturing a group 3 nitride semiconductor template using a double seed layer according to the second embodiment of the present invention will be described in detail with reference to the accompanying drawings.

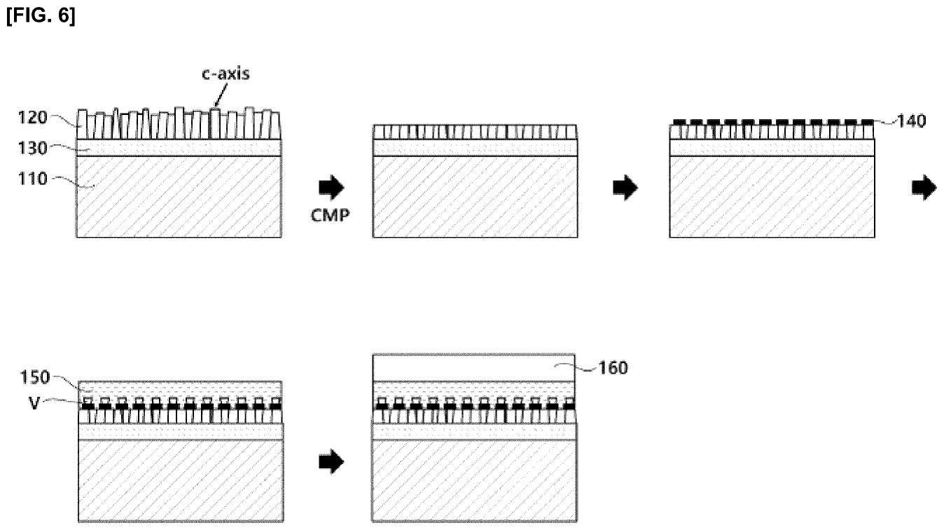

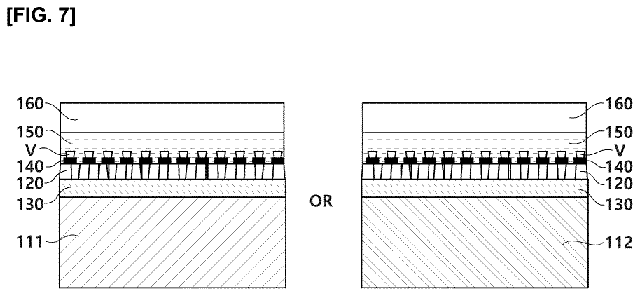

FIG. 5 is a flowchart of a method of manufacturing a group 3 nitride semiconductor template using a double seed layer according to a second embodiment of the present invention, FIG. 6 shows a process of manufacturing a group 3 nitride semiconductor template according to the method of manufacturing a group 3 nitride semiconductor template using a double seed layer according to the second embodiment of the present invention, and FIG. 7 shows group 3 nitride semiconductor templates manufactured on different growth substrates in the method of manufacturing a group 3 nitride semiconductor template using a double seed layer according to the second embodiment of the present invention.

As shown in FIGS. 5 to 7, the method S200 of manufacturing a group 3 nitride semiconductor template using a double seed layer according to the second embodiment of the present invention includes a second seed layer growing operation S210, a first seed layer forming operation S220, a heat treating operation S230, a planarizing operation S240, a stress relief layer growing operation S250, and a device layer growing operation S260.

The second seed layer growing operation S210 is an operation of growing the second seed layer 130 on the growth substrate 110.

The growth substrate 110 is formed by stacking the second seed layer 130, the first seed layer 120, the masking layer 140, the stress relief layer 150, and the power semiconductor device layer 160 thereon, and the growth substrate 110 may be provided as an Si single crystalline growth substrate 111 and as a crystal face, a (111) face in which Si atomic bonds are most dense may be preferentially used, but a (110) or (100) face may also be used depending on the product application. Furthermore, in the case of devices requiring high heat dissipation specifications, the growth substrate 110 may be changed to an SiC growth substrate 112. That is, in the present invention, a growth substrate 110 including Si may be used as the growth substrate 110, and for convenience of description, the following description will be made based on the Si growth substrate 111.

The second seed layer 130 may be grown in-situ on the growth substrate 110 at a high temperature of 900° C. or higher through MOCVD, the second seed layer 130 may be made of AlN, and the thickness of the second seed layer 130 is preferably 200 nm or less.

The first seed layer forming operation S220 is an operation of forming the first seed layer 120 on the second seed layer 130.

Here, the first seed layer 120 is formed ex-situ on the second seed layer 130 at a low temperature of 700° C. or lower through a PVD (sputtering, PLD, and/or an E-beam evaporator) or ALD process, the first seed layer 120 may be formed of AlN or AlNO (within 10 atomic percent (at %) during the layer forming process), similar the second seed layer 130, and the thickness of the first seed layer 120 is preferably 200 nm or less.

In this case, a surface polarity of the first seed layer 120 has a mixed polarity surface in which Al-polarity and N-polarity are mixed and has a surface state in which a c-axis is hardly exposed.

Since the heat treating operation S230 is the same as the method S100 of manufacturing a group 3 nitride semiconductor template using a double seed layer according to the first embodiment of the present invention, overlapping descriptions thereof will be omitted.

The planarizing operation S240 of the present invention is an operation of planarizing the surface of the heat-treated first seed layer 120.

The planarizing operation S240 of the present invention is an operation of improving surface roughness by planarizing the surface of the heat-treated first seed layer 120 through CMP and at the same time, increasing an exposed area of the c-axis.

In this case, the thickness of the first seed layer 120 remaining after CMP is not limited, and a surface roughness value of the first seed layer 120 after CMP is preferably 0.5 nm or less.

The stress relief layer growing operation S250 is an operation of growing the stress relief layer 150 on the first seed layer 120.

More specifically, the stress relief layer growing operation S250 is an operation of growing an AlxGal-xN layer, which is a ternary material in which an Al composition decreases in a gradual or stepwise manner and a Ga composition increases in a gradual or stepwise manner, on the first seed layer 120. In this case, the thickness of the stress relief layer 150 being grown may be preferably 5 μm or less and may have superlattices (SLs) made of AlN/GaN, AlN/AlGaN, AlGaN/GaN, or AlxGal-xN/AlyGal-yN.

In this case, in the stress relief layer growing operation S250, before growing the stress relief layer 150 on the first seed layer 120, the masking layer 140 made of SiNx may be formed. That is, in the stress relief layer growing operation S250, the masking layer 140 may be formed so that SiNx crystal particles are preferentially located in a part in which grain boundaries or defects are present on the surface of the first seed layer 120, and then the stress relief layer 150 may be grown on the first seed layer 120 on which the masking layer 140 is formed, thereby significantly improving the crystal quality of the stress relief layer 150.

Furthermore, in the stress relief layer growing operation S250, a growth mode may be controlled to form an air void V inside the stress relief layer 150.

More specifically, since the masking layer 140 is formed only in the part in which grain boundaries or defects are present on the surface of the first seed layer 120, the masking layer 140 has unevenness, and in the stress relief layer growing operation S250, the stress relief layer 150 may be grown through primary AlN growth reinforced vertically and secondary AlN growth reinforced laterally by the masking layer 140 having such unevenness. According to the growth method, since a number of air voids V may be formed inside the stress relief layer 150, tensile stress may be relieved to effectively suppress the occurrence of cracks in the template and grow the thick stress relief layer 150.

Since the device layer growing operation S260 is the same as the method S100 of manufacturing a group 3 nitride semiconductor template using a double seed layer according to the first embodiment of the present invention, overlapping descriptions thereof will be omitted.

As described above, although all the components constituting embodiments of the present invention are described as being combined or combined to operate as one, the present invention is not necessarily limited to these embodiments. That is, one or more of all the components may be combined to operate as one without departing from the scope of the purpose of the present invention.

In addition, the term such as “comprise,” “constitute,” or “have” described above means that the corresponding component can be included unless otherwise stated, and thus should be construed as further including another component rather than excluding another component. All terms including technical or scientific terms have the same meaning as commonly understood by those skilled in the art to which the present invention pertains unless defined otherwise. Commonly used terms, such as terms defined in dictionaries, should be interpreted as being consistent with the contextual meaning of the related art and are not interpreted in an ideal or excessively formal meaning unless explicitly defined herein.

In addition, the above description is merely an exemplary description of the technical spirit of the present invention, and those skilled in the art to which the present invention pertains will be able to variously modify and change the present invention without departing from the essential characteristics of the present invention.

Therefore, embodiments disclosed in the present invention are not intended to limit the technical spirit of the present invention, but intended to describe the same, and the scope of the technical spirit of the present invention is not limited by these embodiments. The scope of the present invention should be construed by the appended claims, and all technical ideas within the equivalent scope should be construed as being included in the scope of the present invention.

1. A method of manufacturing a group 3 nitride semiconductor template using a double seed layer, the method comprising:
forming a first seed layer on a growth substrate;
heat-treating the first seed layer;
planarizing a surface of the heat-treated first seed layer;
growing a second seed layer on the planarized first seed layer; and
growing a stress relief layer on the second seed layer.

2. The method of claim 1, further comprising growing a power semiconductor device layer on the stress relief layer.

3. The method of claim 1, wherein the first seed layer is formed ex-situ at a low temperature of 700° C. or lower, and
the second seed layer is formed in-situ at a high temperature of 900° C. or higher.

4. The method of claim 1, wherein the planarizing of the surface of the heat-treated first seed layer includes planarizing the surface of the first seed layer through chemical-mechanical polishing (CMP).

5. The method of claim 1, wherein the growing of the second seed layer includes growing the second seed layer on the first seed layer on which a masking layer is formed after forming the masking layer on a part in which grain boundaries or defects are present in the surface of the first seed layer.

6. The method of claim 5, wherein air voids are formed inside the second seed layer.

7. A method of manufacturing a group 3 nitride semiconductor template using a double seed layer, the method comprising:
growing a second seed layer on a growth substrate;
forming a first seed layer on the second seed layer;
heat-treating the first seed layer;
planarizing a surface of the heat-treated first seed layer; and
growing a stress relief layer on the planarized first seed layer.

8. The method of claim 7, further comprising growing a power semiconductor device layer on the stress relief layer.

9. The method of claim 7, wherein the first seed layer is formed ex-situ at a low temperature of 700° C. or lower, and
the second seed layer is formed in-situ at a high temperature of 900° C. or higher.

10. The method of claim 7, wherein the planarizing of the surface of the first seed layer includes planarizing the surface of the first seed layer through chemical-mechanical polishing (CMP).

11. The method of claim 7, wherein the growing of the stress relief layer includes growing the stress relief layer on the first seed layer on which a masking layer is formed after forming the masking layer on a part in which grain boundaries or defects are present in the surface of the first seed layer.

12. The method of claim 11, wherein air voids are formed inside the stress relief layer.
